(19) United States
(12) Patent Application Publication
(10) Pub. No.: US 2007/0080403 A1
(43) Pub. Date: Apr. 12, 2007

(54) Low trigger voltage electrostatic discharge protection device

(76) Inventors: David Litfin, Houlton, WI (US); Steven Kosier, Lakeville, MN (US)

Correspondence Address: KINNEY & LANGE, P.A., THE KINNEY & LANGE BUILDING, 312 SOUTH THIRD STREET, MINNEAPOLIS, MN, 55415-1002, US

(21) Appl. No.: 11/244,959

(22) Filed: Oct. 6, 2005

(51) Int. Cl. H01L 23/62

(52) U.S. Cl. 257/360

(57) ABSTRACT

An ESD protection device with a low trigger voltage includes a semiconductor layer, a lightly doped well region formed in the semiconductor layer, a highly doped anode region formed in the well region, a highly doped cathode region formed in the semiconductor layer, a highly doped bridging region bridging a junction between the semiconductor layer and the well region, and a highly doped channel stop region of formed in semiconductor layer between the cathode region and the bridging region. The trigger voltage may be adjusted over a range of voltages, and the ESD protection devices may be connected in parallel in order to be effective in very high current situations.

### BACKGROUND OF THE INVENTION

The invention relates generally to electrostatic discharge (ESD) protection devices. More particularly, it relates to ESD protection devices used with integrated circuits.

Integrated circuits are vulnerable to damage from electrostatic discharge (ESD) from a charged body, such as a human being, that physically contacts the integrated circuit. Transient voltages caused by the ESD may severely damage or destroy an integrated circuit. ESD protection devices are typically placed at each external terminal of the integrated circuit, where they can intercept the transient voltage spikes caused by ESD.

Essentially, an ESD protection device is a switch that is turned on by a transient voltage spike and that provides a safe discharge path for the current associated with the transient voltage spike. ESD protection devices generally operate by providing a very high resistance (essentially an open circuit) during normal operation of the integrated circuit. However, if an electrostatic discharge creates a sufficiently large spike in voltage, the ESD protection device turns on and provides a very low resistance path that shunts current away from the portion of the integrated circuit that may be damaged by the voltage spike, thereby protecting the integrated circuit.

A variant of a silicon controlled rectifier (SCR), a thyristor, is a commonly used ESD protection device. Thyristors are semiconductor devices that consist of a PNPN or NPNP series of layers. Thyristors can be switched between a high impedance/low current OFF state and a low impedance/high current ON state.

A thyristor is modeled as two bipolar transistors: a PNP transistor and an NPN transistor in which the base of the PNP transistor is connected to the collector of the NPN transistor and the collector of the PNP transistor is connected to the base of the NPN transistor. The PNP emitter acts as the anode of the thyristor and the NPN emitter acts as the cathode. A voltage is applied to the anode and the cathode is held to ground. During normal operation, both transistors are reversed biased and therefore in cut-off. When a voltage spike occurs at the anode, it forward biases the emitter-base junction of the PNP transistor, and the PNP transistor turns on. The current through the PNP transistor flows into its collector, which is also the base of the NPN transistor. As a result, the emitter-base junction of the NPN transistor becomes forward biased, and it also turns on. Current flows from the collector of the NPN transistor to the emitter of the NPN transistor, which is also the base of the PNP transistor. This forward-biases the PNP transistor, so that the voltage at the emitter of the PNP transistor (i.e., the voltage spike) is no longer needed to provide the bias for the PNP transistor to stay turned on.

Two important parameters for the thyristor are the trigger voltage (V_{trig}) and the trigger current (I_{trig}). The trigger voltage is the amount of voltage that is required to forward bias the emitter-base junction of the PNP transistor. The trigger current is the amount of current that is needed to forward bias the emitter-base junction of the PNP transistor. That is, the PNP transistor will not be forward biased, and the thyristor will not turn on, unless the transient voltage spike has a voltage of at least the trigger voltage and a current of at least the trigger current.

Another important parameter for the thyristor is the holding voltage (Vₕ). Once both transistors of the thyristor are turned on, the voltage begins to decrease, which results in a negative resistance. The holding voltage is the minimum value of the voltage required to keep the thyristor turned-on, and it is defined by the amount of current that the PNP transistor must supply to forward bias the NPN transistor.

When used as an ESD protection circuit, the thyristor is usually connected as a two terminal device, with the emitter and base of the PNP transistor tied together and the emitter and base of the NPN transistor tied together. Triggering requires avalanche breakdown of a reverse biased PN junction. The thyristor turns on either when the emitter of the NPN transistor is forward biased by the hole current in its P region base or when the PNP transistor is turned on by the electron current in its N region base. Typically, the NPN transistor gain is an order of magnitude higher than the PNP transistor gain at low current levels, so turning on the NPN transistor is easier than turning on the PNP transistor.

In designing ESD protection devices, it is preferred that the device can be implemented using standard fabrication techniques. Furthermore, the ESD protection device should take up little room on the integrated circuit, avoid latch-up under normal operating conditions, and it should operate in an appropriate range of voltages. For example, if a circuit typically operates at 5 volts, an ESD protection device that does not turn on unless a voltage spike exceeds 50 volts is not practical, since a spike of 45 volts, for instance, will not trigger the ESD protection device, but will probably damage the 5 volt circuit.

The trigger voltage of a typical thyristor fabricated in a modern sub-micron process is about 40-50 volts. In order to make the thyristor a practical ESD protection device, this trigger voltage must be reduced. One way of doing this is shown in U.S. Pat. 4,939,616, which discloses an ESD protection device in which an N-type diffusion bridges the boundary between an N-well and a P-substrate. This highly-doped bridging region assists the triggering of the thyristor because of the reduced avalanche breakdown voltage at the junction between the relatively highly doped N-region and the P-substrate, as compared with the breakdown voltage at the junction between the lightly doped N-well and the P-substrate. Using this highly-doped region bridging the N-well and P-substrate region can reduce the trigger voltage of the thyristor to about 20 volts.

Another addition to the basic thyristor is shown in U.S. Pat. No. 5,465,189. In this ESD protection device, the N-type region bridging the boundary between the N-well and the P-region is gated, thereby forming a MOS transistor. A dielectric gate oxide is formed over the highly doped N-region, and a polysilicon or metal electrode is placed on top of the oxide. By applying a potential to the gate, the potential of the P-region can be lowered, resulting in a decreased trigger voltage.

However, the need still exists for a thyristor with a lower trigger voltage. Even if the trigger voltage can be reduced to 20 volts, a typical integrated circuit that runs at 5 volts may be severely damaged by a transient voltage of less than 20 volts. In addition, the oxide needed to create a gated structure such as that shown in U.S. Pat. No. 5,465,189 is fragile and may become damaged through repeated use, resulting in a less robust ESD protection device. Also, some fabrication processes do not allow the option of creating MOS gates.

### SUMMARY OF THE INVENTION

An ESD protection device with a low trigger voltage includes a semiconductor layer, a lightly doped well region formed in the semiconductor layer, a highly doped anode region formed in the well region, a highly doped cathode region formed in the semiconductor layer, a highly doped bridging region bridging a junction between the semiconductor layer and the well region, and a highly doped channel stop region formed in semiconductor layer between the cathode region and the bridging region.

### BRIEF DESCRIPTION OF THE DRAWINGS

FIG. 1 is a cross-sectional view of an ESD protective device according to one embodiment of the invention.

FIG. 2 is a current-voltage (IV) graph showing the current-voltage relationship of the invention in comparison to conventional ESD protection devices.

FIG. 3 is a cross-sectional view of a second embodiment of the invention.

FIG. 4 shows a simplified layout of ESD protection devices on an integrated circuit chip.

FIG. 5 is a current-voltage (IV) graph showing the current-voltage relationship of ESD protection devices in parallel.

While the above-identified drawing figures set forth embodiments of the invention, other embodiments are also contemplated, as noted in the discussion. In all cases, this disclosure presents the invention by way of representation, and not limitation. It should be understood that numerous other modifications and embodiments that fall within the scope and spirit of the principles of this invention can be devised by those skilled in the art. The figures may not be drawn to scale.

### DETAILED DESCRIPTION

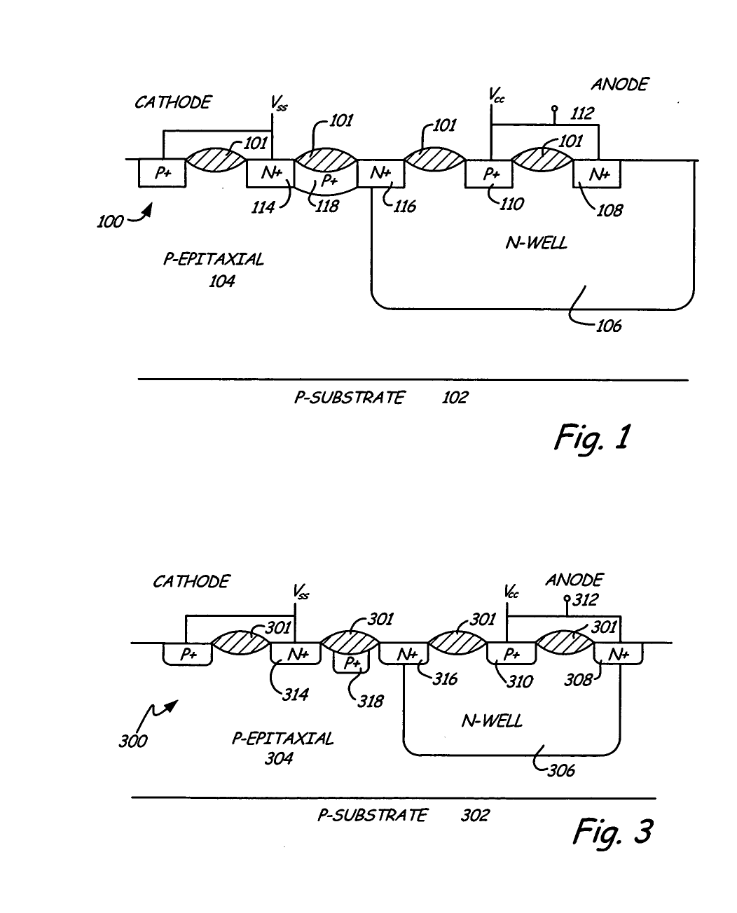

FIG. 1 shows an implementation of the present invention. ESD protection device 100 is built upon P-type semiconductor substrate 102. P-epitaxial layer 104 is grown on P-substrate 102 forming a P-type region, and N-well 106 is located in P-epitaxial layer 104. On the surface of the circuit, heavily doped N-region 108 and heavily doped P-region 110 are located in N-well 106. Heavily doped P-region 110 is connected to supply voltage V_{CC} and functions as the anode of the ESD protection device. Both heavily doped N-region 108 and heavily doped P-region 110 are connected to input 112. Heavily doped N-region 114 is located in P-epitaxial layer 104 and functions as the cathode of the device. Highly doped N-region 116 bridges N-well 106 and P-epitaxial region 104. A field oxide 101 separates the components at the surface. Channel stop region 118, which is a highly doped P-region, is located between highly doped N-region 114 and highly doped N-region 116.

In operation, ESD protection device 100 works as two transistors. A PNP transistor is formed by heavily doped P-region 110 as the emitter; N-well 106 as the base; and P-substrate 102 and P-epitaxial region 104 as the collector. An NPN transistor is formed by heavily doped N-layer 114 as the emitter; channel stop region 118 and P-epitaxial region 104 as the base; and heavily doped N-region 116, N-well 106 and heavily doped N-region 108 as collector. The PNP emitter (heavily doped P-region 110) acts as the anode of ESD protection device 100 and the NPN emitter (heavily doped N-region 114) acts as the cathode.

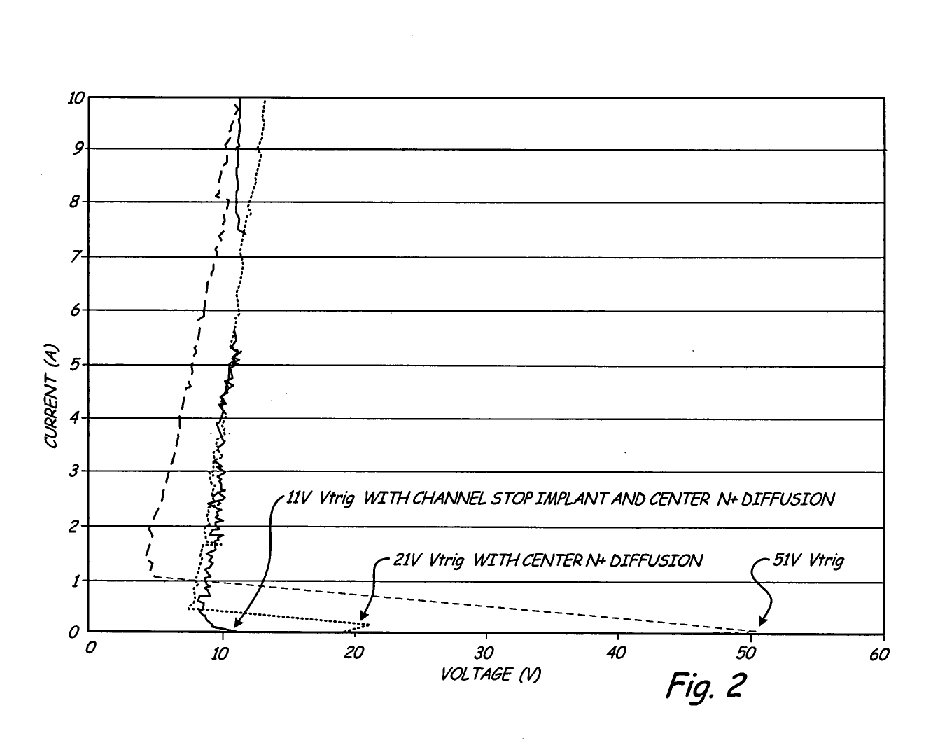

ESD protection device 100 is similar to a conventional thyristor, such as that disclosed in FIG. 3 of U.S. Pat. No. 4,939,616. However, the addition of channel stop region 118 greatly reduces the trigger voltage of ESD protection device 100. Channel stop region 118 is a highly-doped P region. By replacing P-epitaxial region 104 with the more highly doped channel stop region 118 as the base of the NPN transistor, the breakdown voltage at the base-collector junction of the NPN transistor is greatly reduced.

One skilled in the art will recognize that the embodiment of the invention shown in FIG. 1 is an example that shows the relationship between positively and negatively doped regions in ESD protection device 100, and the invention is not limited to the exact structure shown. Design of microelectronic structures is a complex process that necessarily involves many decisions and many trade-offs. Doped regions may be created in different ways, such as by diffusion or epitaxial growth, without changing the basic nature in which they function. Thus, for example, p-epitaxial region 104 might, in practice, be a p-tub region that is diffused into an n-tub region, without changing the nature in which the invention functions. Also, positively and negatively doped regions could be reversed.

FIG. 2 is a current-voltage (IV) graph comparing the current-voltage relationship in ESD protection device 100 to the current-voltage relationships in conventional ESD protection devices. As shown in FIG. 2, a basic thyristor has a trigger voltage of 51 volts and a holding voltage of 5-10 volts. A thyristor with highly doped N-region 116 bridging N-well 106 and P-epitaxial region 104 (a structure like that shown in U.S. Pat. No. 4,939,616) has a trigger voltage of about 21 volts and a holding voltage of 8-11 volts. In contrast, ESD protection device 100, which includes both channel stop region 118 and highly doped N-region 116 has a trigger voltage of less than 12 volts and a holding voltage of less than 10 volts. The measurements shown in FIG. 2 were measured using the standard ESD device testing method of Transmission Line Pulsing.

While reducing the trigger voltage is generally desirable for an ESD protection device, a circuit designer may prefer to select an optimal trigger voltage for a circuit. Thus, the trigger voltage of an ESD protection device could be adjusted through a range of voltages to suit the particular needs of the circuit. The present invention may be used to adjust the trigger voltage over a range of values.

FIG. 3 shows an alternative embodiment of the invention. ESD protection device 300 is built upon P-type semiconductor substrate 302. P-epitaxial layer 304 is grown on P-substrate 302 forming a P-type substrate region, and N-well 306 is located in P-epitaxial layer 104. On the surface of the circuit, heavily doped N-region 308 and heavily doped P-region 310 are located in N-well 306. Heavily doped P-region 310 is connected to supply voltage V_{cc} and functions as the anode of the ESD protection device. Both heavily doped N-region 308 and heavily doped P-region 310 are connected to input 312. Heavily doped N-region 314 is located in P-epitaxial layer 304 and functions as the cathode of the device. Highly doped N-region 316 bridges N-well 306 and P-epitaxial region 304. A field oxide 301 separates the components at the surface. Channel stop region 318, which is a highly doped P-region, is located between highly doped N-region 314 and highly doped N-region 316. ESD protection device 300 is similar in structure to ESD protection device 100 shown in FIG. 1, except that channel stop region 318 is separated from highly doped N-region 314 and highly doped N-region 316.

In operation, ESD protection device 300 works in the same way as ESD protection device 100. A PNP transistor is formed by heavily doped P-region 310 as the emitter; N-well 306 as the base; and P-substrate 302 and P-epitaxial region 304 as the collector. An NPN transistor is formed by heavily doped N-layer 314 as the emitter; channel stop region 318 and P-epitaxial region 304 as the base; and heavily doped N-region 316, N-well 306 and heavily doped N-region 308 as collector. The PNP emitter (heavily doped P-region 310) acts as the anode of ESD protection device 300 and the NPN emitter (heavily doped N-region 314) acts as the cathode.

However, ESD protection device 300 differs from ESD protection device because it has a higher trigger voltage, assuming ESD protection device 100 and ESD protection device 300 are identical, except for the location of channel stop region 318. By altering the distance between the collector region (highly doped N-region 314) and base region (channel stop region 318) and the distance between the emitter region (highly doped N-region 316) and base region (channel stop region 318) of the NPN transistor, the circuit designer can control the trigger voltage of an ESD protection device. For instance, as previously noted, the device shown in FIG. 1 has a trigger voltage of about 11 volts. By separating the base from the emitter and collector, the trigger voltage may be increased to 15 volts or 20 volts or higher, should the circuit designer think that such a trigger voltage is appropriate. One skilled in the art will recognize that the trigger voltage of ESD protection device 300 may be altered over a range of values by appropriate placement of the channel stop region.

In conventional thyristors the holding voltage is significantly lower than the trigger voltage, as can be seen in FIG. 2. However, as can also be seen in FIG. 2, the holding voltage of the embodiment of the invention shown in ESD protection device 100 approaches the trigger voltage at high current. This allows multiple thyristors to be cascaded and used in parallel, thereby allowing the creation of ESD protection circuits that are able to shunt away large amounts of current.

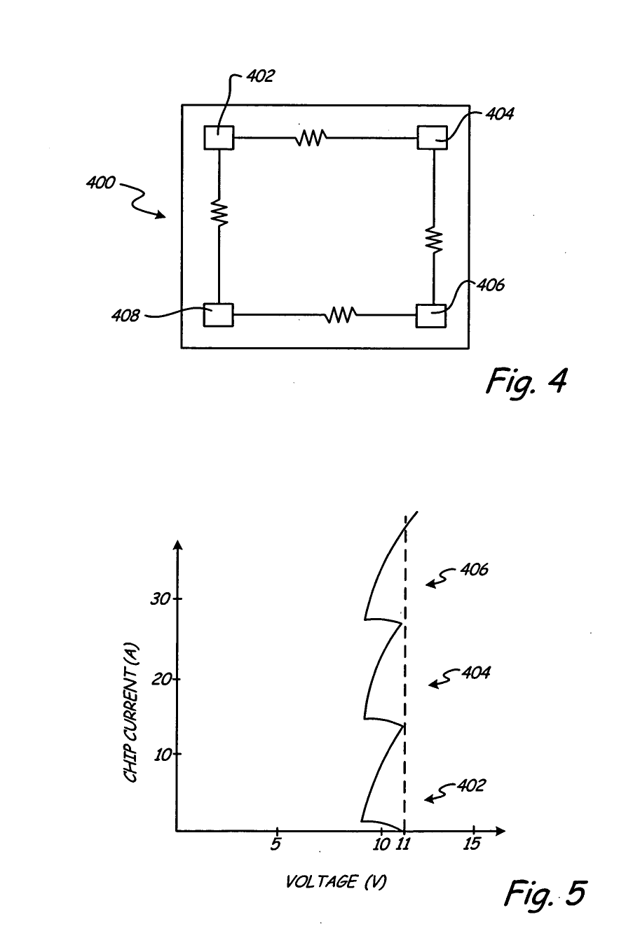

FIG. 4 shows a simplified example of ESD protection devices on an integrated circuit. An electrostatic discharge can be discharged at any pin on integrated circuit 400. Integrated circuit 400 has four ESD protection devices, 402, 404, 406 and 408, located at the four corners of the chip. ESD protection devices 402, 404, 406 and 408 all have a structure like that of ESD protection device 100 and a current-voltage profile like that shown in FIG. 2. If a voltage spike triggers ESD protection device 402 by exceeding its trigger voltage of about 11 volts, ESD protection device 402 will turn on. It will then shunt current away from the circuit that is being protected. If the current is high enough (more than about 7 amperes for the device shown in FIG. 2), the holding voltage of ESD protection device 402 exceeds 11 volts, thereby triggering ESD protection device 404. ESD protection device 404 will then also shunt current away from the circuit that is being protected. However, if the current through ESD protection device 404 is high enough, the holding voltage of ESD protection device 404 also exceeds 11 volts, thereby triggering ESD protection device 406. Similarly, if the current through ESD protection device 406 is high enough, the holding voltage of ESD protection device 406 may exceed 11 volts, thereby triggering ESD protection device 408. This use of cascading ESD protection devices may be used with any number of ESD protection devices on a chip, resulting in increased ESD protection because of the ability to shunt away large amounts of current.

Reducing the trigger voltage of a thyristor to very nearly the holding voltage of the thyristor is necessary in order to cascade thyristors as described with respect to FIG. 4. Otherwise, if the trigger voltage of a thyristor is much greater than its holding voltage, then an individual thyristor will be destroyed before any of the additional cascaded thyristors are activated. For example, a typical thyristor as shown in FIG. 2 has a trigger voltage of 21 volts and a holding voltage of about 10 volts. If such a typical thyristor is used as an ESD protection device, it cannot be cascaded like the example shown in FIG. 5, because it would never reach the 21 volt trigger current needed to turn on an additional thyristor used as an ESD protection device. Thus, the low trigger voltage thyristor of the present invention can be applied in a new way, which is not possible with prior art thyristors.

FIG. 5 is an IV curve showing the use of the cascaded thyristors shown in FIG. 4. As the current through ESD protection device 402 increases, the holding voltage approaches the triggering voltage of 11 volts. At sufficiently high current, the holding voltage of ESD protection device 402 will reach the trigger voltage of ESD protection device 404, and ESD protection device 404 will be activated. If the current is high enough, the holding voltage of ESD protection device 404 will reach the trigger voltage of ESD protection device 406, and ESD protection device 406 will be activated. Cascaded ESD protection devices can be applied with any number of ESD protection devices, thereby allowing the design of an ESD protection device that is able to shunt away large amounts of current.

The present invention is an ESD protection device with a low trigger voltage. As a result, it is able to better protect sensitive circuits that typically operate at about 5 volts. It is less fragile and more robust than ESD protection devices that rely on MOS gates to reduce the trigger voltage. It is also possible to use the invention in bipolar-only fabrication processes, in which creating MOS gates is not an option. In addition, the trigger voltage of the invention may be adjusted over a range of voltages by proper placement of the channel stop region. Finally, since V_{trig} is very nearly the holding voltage, the ESD protection devices utilizing the invention can be cascaded in parallel, and placed evenly throughout the integrated circuit thereby allowing the design of ESD protection devices that are able to shunt away very large amounts of current from the sensitive integrated circuits that the ESD devices protect.

Although the present invention has been described with reference to preferred embodiments, workers skilled in the art will recognize that changes may be made in form and detail without departing from the spirit and scope of the invention.

1. An electrostatic discharge protection device comprising:
a semiconductor layer of a first conductivity type;
a well region of a second conductivity type formed in the semiconductor layer;
an anode region of a first conductivity type formed in the well region;
a cathode region of a second conductivity type formed in the semiconductor layer;
a bridging region of a second conductivity type formed in both the semiconductor layer and the well region and bridging a junction between the semiconductor layer and the well region; and
a channel stop region of a first conductivity type formed in the semiconductor layer between the cathode region and the bridging region.

2. The electrostatic discharge protection device of claim 1 wherein the first conductivity type is p-type and the second conductivity type is n-type.

3. The electrostatic discharge protection device of claim 1 wherein the first conductivity type is n-type and the second conductivity type is p-type.

4. The electrostatic discharge protection device of claim 1 wherein the device is formed on an integrated circuit.

5. The electrostatic discharge protection device of claim 1 wherein the trigger voltage is less than 12 volts.

6. The electrostatic discharge protection device of claim 1 wherein the channel stop region is adjacent to both the cathode region and the bridging region.

7. The electrostatic discharge protection device of claim 1 wherein the channel stop region is separated by a lateral distance from both the cathode region and the bridging region.

8. The electrostatic discharge protection device of claim 7 wherein the ESD protection device has a trigger voltage, and the trigger voltage of the device is adjusted by changing the lateral distance between the channel stop region and the cathode and bridging regions.

9. The electrostatic discharge protection device of claim 1 wherein the holding voltage reaches the trigger voltage at high current.

10. The electrostatic discharge protection device of claim 9 wherein a plurality of ESD protection devices are cascaded in parallel.

11. An electrostatic discharge protection device comprising:
a n region formed in a p region;
a first p+ region formed in the n region and defining an anode;
a first n+ region formed in the p region, the first n+ region being laterally spaced from the first p+ region and defining a cathode;
a second n+ region formed in both the n region and the p region and laterally spaced from both the first p+ region and the first n+ region;
a second p+ region formed in the p material between the first n+ region and the second n+ region.

12. The electrostatic discharge protection device of claim 11 wherein the second p+ region is adjacent to both the first n+ region and the second n+ region.

13. The electrostatic discharge protection device of claim 11 wherein the second p+ region is spaced apart from both the first n+ region and the second n+ region.

14. The electrostatic discharge protection device of claim 13 wherein the ESD protection device has a trigger voltage, and the trigger voltage of the device is adjusted by changing the spacing between the second p+ region and the first and second n+ regions.

15. The electrostatic discharge protection device of claim 11 wherein the device is formed on an integrated circuit.

16. The electrostatic discharge protection device of claim 1 wherein the device has a trigger voltage of less than 12 volts.

17. The electrostatic discharge protection device of claim 1 wherein the holding voltage reaches the trigger voltage at high current.

18. The electrostatic discharge protection device of claim 17 wherein a plurality of ESD protection devices are cascaded in parallel.
